(19) United States
(12) Patent Application Publication
(10) Pub. No.: US 2005/0045918 A1
(43) Pub. Date: Mar. 3, 2005

(54) Hybrid vertical twisted bitline architecture

(76) Inventor: Armin Reith, Munchen (DE)

Correspondence Address: SLATER & MATSIL, L.L.P., 17950 PRESTON RD, SUITE 1000, DALLAS, TX, 75252-5793, US

(21) Appl. No.: 10/653,741

(22) Filed: Sep. 2, 2003

(51) Int. Cl. H01L 27/10

(52) U.S. Cl. 257/208

(57) ABSTRACT

A method and apparatus of wiring a twisted signal such as those that may be used in a twisted bitline architecture of a memory. The twisted bitline architecture includes mixing twisted bitline pairs and hybrid twisted bitline pairs to form a memory array. The twisted bitline pair includes two bitlines, such as a bitline-true line and a bitline-complementary line. The bitlines are formed on two metal layers, M0 and M1. Metal layer M1 is used to accomplish a twist in the bitline and allowing the bitline on metal layer M0 to be moved to metal layer M1, and the bitline on metal layer M1 to be moved to metal layer M0. The hybrid twisted bitline pair includes two bitlines. The first bitline extending over approximately one-half of the width of the memory array on metal layer M0. The second bitline extends over one-half of the width of the memory array on metal layer M1 and the remained on metal layer M1.

### TECHNICAL FIELD

The present invention relates to the field of memory devices, and more specifically, to a vertical twisted bitline architecture having a hybrid twist between two metal layers.

### BACKGROUND

Many memory arrays, such as a dynamic random access memory (DRAM) arrays, have multiple memory cells accessible by a word line and a bitline. A DRAM memory cell generally has a storage capacitor coupled between an access transistor and a constant voltage source. The gate of the access transistor is electrically coupled to the word line. The source and drain of the access transistor are electrically coupled to a bitline and the storage capacitor, respectively.

In operation, the word line enables the access transistor to allow data to be written to and read from the storage capacitor. During a read operation, the word line is enabled and the electronic charge stored in the storage capacitor is allowed to flow to the bitline. During a write operation, the word line is enabled and the electronic charge on the bitline is allowed to flow to the storage capacitor.

The bitline is electrically coupled to a sense amplifier. Generally, the sense amplifier receives two bitlines: a bitline-true (BL-true) and bitline-complementary (BL-complementary). The BL-true is electrically coupled to one or more memory cells and represents the value stored in the storage capacitor. The BL-complementary is the complement to the BL-true or a reference value. In some types of DRAMs, the BL-complementary is held at a constant high voltage. The sense amplifier senses the difference between the BL-true and the BL-complementary lines to determine if the value stored in the storage capacitor was a logic “1” or a logic “0.”

To reduce the size, DRAMs are commonly fabricated as multi-layered semiconductor devices. Storage capacitors may be beneath or above the bitlines. Bitlines may be fabricated on upper or lower layers. As the DRAMS become smaller, however, the distance between the bitlines becomes smaller and the noise and interference generated by neighboring bitlines increases. Attempts have been made to utilize a twisted bitline architecture to reduce the noise and interference from neighboring bitlines. The attempts, however, generally require either additional metal layers or complicated descrambling schemes. For example, one such attempt disclosed in U.S. Pat. No. 6,282,113 B1 to DeBrosse, entitled “Four F-Squared Gapless Dual Layer Bitline DRAM Array Architecture,” requires a complicated descrambling scheme, and another attempt disclosed in U.S. Pat. No. 6,430,076 B1 to Mueller et al., entitled “Multi-Level Signal Lines With Vertical Twists,” utilizes a third metal layer. Therefore, there is a need for simplified bitline architecture that requires less area.

### SUMMARY OF THE INVENTION

These and other problems are generally reduced, solved or circumvented, and technical advantages are generally achieved, by embodiments of the present invention which provide a hybrid vertical twisted pair bitline architecture.

In one embodiment of the present invention, a hybrid twisted pair is provided. The hybrid twisted pair includes a first bitline and a second bitline. The first bitline extends over approximately one-half of the width of the memory array on a first metal layer. The second bitline extends over approximately one-half of the memory array on a second metal layer. An interlayer connector moves the second bitline from the first metal layer to the second metal layer where the second bitline extends over the remaining half of the memory array.

In another embodiment of the present invention, the hybrid twisted pair is integrated with a twisted pair of bitlines. The twisted pair of bitlines use a first metal layer to twist the bitlines, moving the one bitline from the first metal layer to the second metal layer and moving the other bitline from the second metal layer to the first metal layer.

In another embodiment of the present invention, the hybrid twisted pair and the twisted pair of bitlines are arranged in an alternating manner.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 is a plan view of metal layer M1 having a hybrid vertical twist bitline architecture formed thereon in accordance with one embodiment of the present invention;

FIG. 2 is a plan view of metal layer M0 having a hybrid vertical twist bitline architecture formed thereon in accordance with one embodiment of the present invention;

FIG. 3 is a cross-section view of one bitline pair of a hybrid vertical twist bitline architecture formed in accordance with one embodiment of the present invention;

FIG. 4 is a cross-section view of another bitline pair of a hybrid vertical twist bitline architecture formed in accordance with one embodiment of the present invention; and

FIG. 5 is a plan view of a twist area to twist a bitline pair in accordance with one embodiment of the present invention.

### DETAILED DESCRIPTION OF ILLUSTRATIVE EMBODIMENTS

The making and using of the presently preferred embodiments are discussed in detail below. It should be appreciated, however, that embodiments of the present invention provide many applicable inventive concepts that can be embodied in a wide variety of specific contexts. The specific embodiments discussed are merely illustrative of specific ways to make and use the invention, and do not limit the scope of the invention.

For example, one embodiment of the present invention is a twisted bitline architecture. The discussions that follow describe embodiments of the present invention in which the twisted bitline architecture is utilized in a DRAM array. Embodiments of the present invention, however, may be utilized in other types of devices in which a pair of current-carrying lines may be subject to noise and interference from other lines, such as SRAM, EEPROM, FRAM, RAM, ROM, other types of memory devices, or the like. Aspects of the invention could also be used in a logic device or any other chip that includes differential signal lines.

As will be described below, the preferred embodiment of the present invention utilizes two metal layers, M0 and M1, to route a pair of conducting lines, such as BL-true and BL-complementary of a DRAM. Metal layer M0 electrically couples the bitline, preferably BL-true, to individual memory cells. Metal layer M1 is utilized to accomplish a twist in the bitline pair. Generally, a twist is accomplished by moving the bitline on metal layer M0 to metal layer M1, and moving the bitline on metal layer M1 to metal layer M0.

Furthermore, the memory arrays discussed and illustrated herein assume that the word lines are substantially perpendicular to the bitlines as is common in the industry. However, the present invention may be used in memory devices with varying configurations, including configurations in which the word lines and the bitlines are not perpendicular.

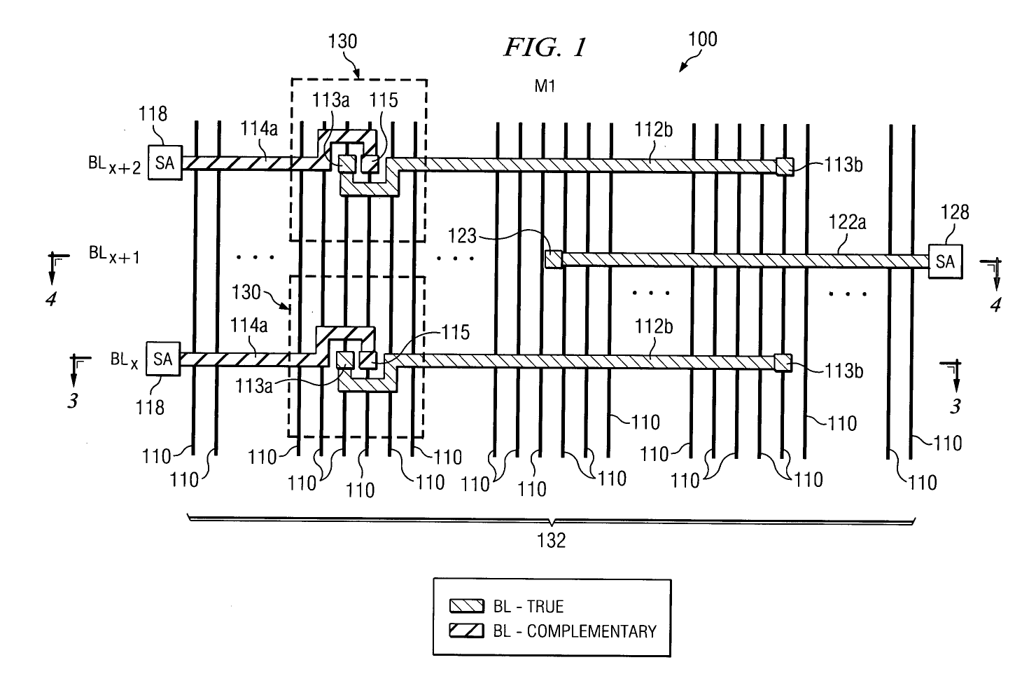

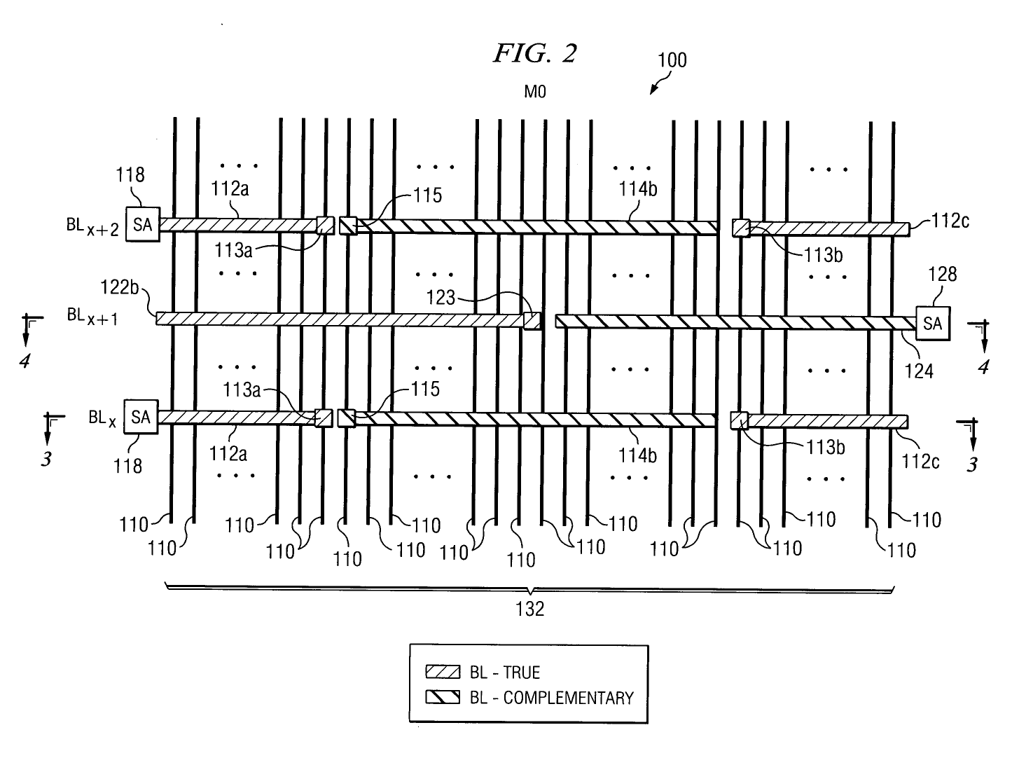

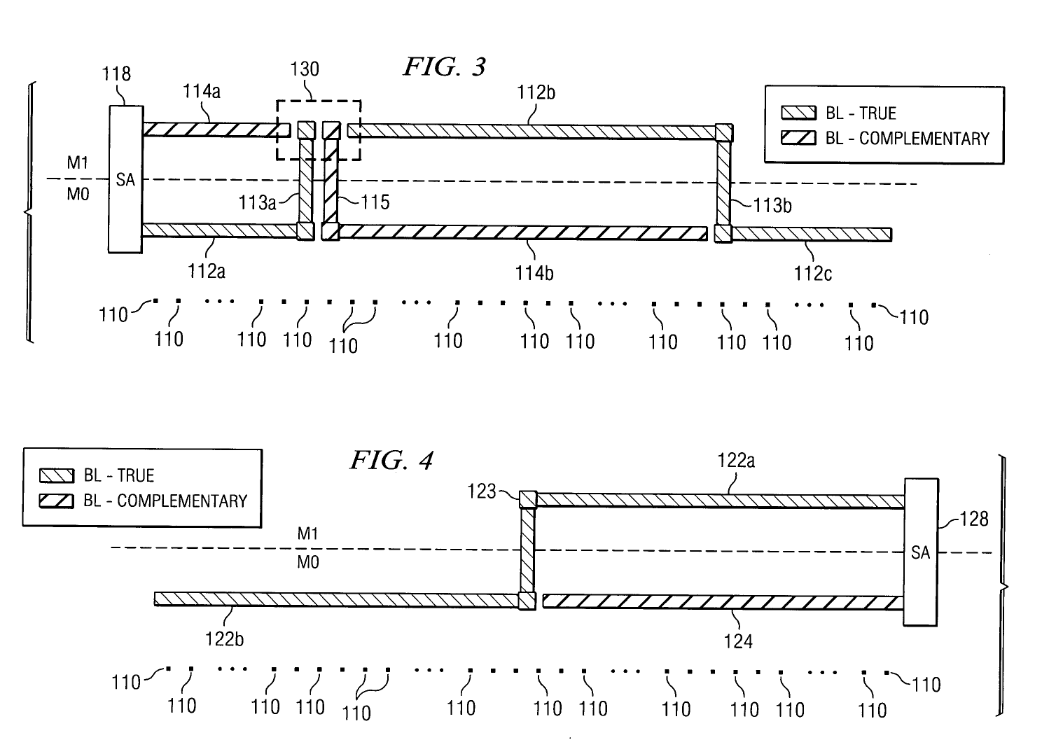

Accordingly, FIGS. 1 and 2 show a plan view of a portion 100 of metal layers M1 and M0, respectively, of a DRAM in accordance with one embodiment of the present invention. Futhermore, FIGS. 3 and 4 show a cross-section view of an even bitline, such as bitline BLₓ, and an odd bitline, such as BLₓ₊₁, respectively.

The portion 100 illustrates one method of routing bitline pairs in accordance with the preferred embodiment in which the bitline pairs are routed in an alternating manner. For example, the embodiment illustrated in FIGS. 1-4 shows a method of routing bitline pairs wherein the even bitline pairs (e.g., BLₓ and BLₓ₊₂) are routed in one manner and the odd bitline pairs (e.g., BLₓ₊₁) are routed in another manner. As will be explained in greater detail below, alternating the routing scheme of the bitlines allows the bitlines to be fabricated closer together while reducing the noise and interference between bitlines. It is understood that the architecture illustrated in FIGS. 1 and 2 may be repeated to create larger memory structures.

The portion 100 includes word lines 110, BL-true lines 112a-c and 122a-b, BL-complementary lines 114a-b and 124, interlayer connectors 113a-b, 115 and 123, and sense amplifiers 118 and 128. It is noted that the word lines 110 are not generally physically located on the metal layers M0 or M1, but are shown in the figures for illustrative purposes only. Furthermore, it is noted that for illustrative purposes, the BL-true lines 112a-c and 122a-b are shown as black lines, and the BL-complementary lines 114a-b and 124 are shown as white lines.

Regarding the even bitlines, such as bitline BLₓ, BL-complementary 114a located on metal layer M1 is electrically coupled to the sense amplifier 118. BL-complementary 114a electrically couples the sense amplifier 118 to the interlayer connector 115 located in a twist region 130 on metal layer M1. The interlayer connector 115 electrically couples BL-complementary 114a to BL-complementary 114b located on metal layer M0 (see FIG. 2). BL-complementary 114b extends on metal layer M0 toward the side opposite of the sense amplifier 118 of the word line region 132.

Beginning on metal layer M0, BL-true 112a electrically couples the sense amplifier 118 to the interlayer connector 113a. The interlayer connector 113a electrically couples BL-true 112a on metal layer M0 to BL-true 112b on metal layer M1 in the twist region 130. From the twist region 130, BL-true 112b electrically couples the interlayer connector 113a to the interlayer connector 113b, which electrically couples BL-true 112b on metal layer M1 to BL-true 112c on metal layer M0.

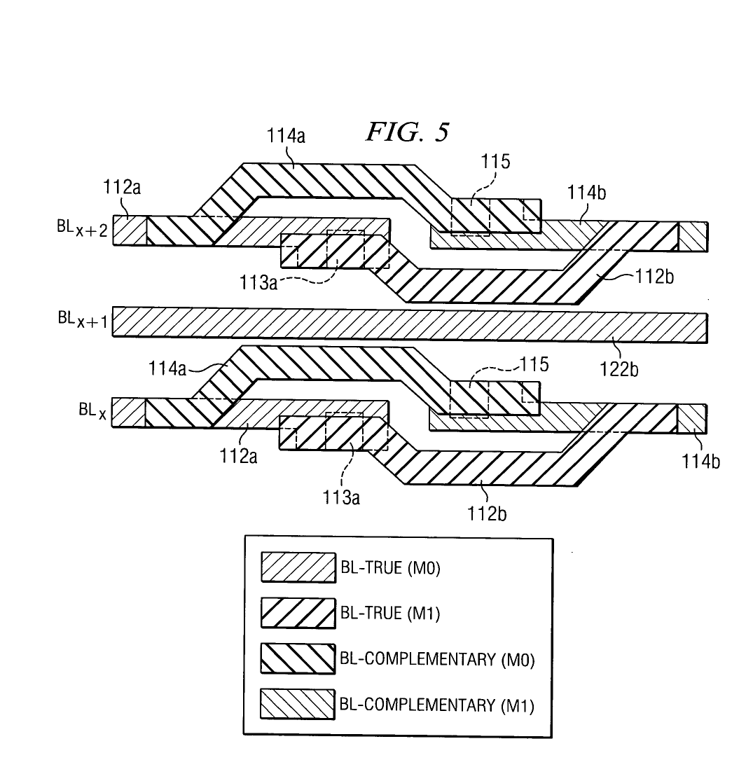

Preferably the twist region 130 and the interlayer connector 113b are located at opposing sides of the word line region 132, most preferably about one-quarter of the width of the word line region from the edge of the word line region. The twist region 130 allows BL-complementary 114a to be transferred to metal layer M0 and allows BL-True 112a to be transferred to metal layer M1. The twist region 130 is discussed in greater detail below with reference to FIG. 5.

Regarding the odd bitlines, such as bitline BLₓ₊₁, BL-true 122a electrically couples the sense amplifier 128 to the interlayer connector 123 on metal layer M1. The interlayer connector 123 electrically couples BL-true 122a on metal layer M1 to BL-true 122b on metal layer M0. BL-true 122b extends toward the side opposite of the sense amplifier 128 of the word line region 132.

On metal layer M0, a BL-complementary 124 is electrically coupled to the sense amplifier 128 and extends to a memory cell (not shown) in the approximate area vertically adjacent to the interlayer connector 123, where it ends.

In the preferred embodiment, as illustrated in FIGS. 1-4, the sense amplifiers 118 electrically coupled to the even bitlines and the sense amplifiers 128 electrically coupled to the odd bitlines are situated on opposing sides of the word line region 132. For example, the sense amplifiers 118 are situated on the left side of the word line region 132, and the sense amplifier 128 is situated on the right side of the word line region 132.

FIG. 5 shows an enlarged plan view of the twist region 130 (FIG. 1) that may be used in accordance with the present invention. The lines filled with a forward slash (“/”) represent bitlines on metal layer M0, and lines filled with a backward slash (“\”) represent bitlines on metal layer M1.

As discussed above, the even bitlines (e.g., BLₓ and BLₓ₊₂) have BL-true 112a on metal layer M0 and are electrically coupled to the interlayer connector 113a. The interlayer connector 113a electrically couples BL-true 112a on metal layer M0 to BL-true 112b on metal layer M1. Similarly, BL-complementary 114a on layer M1 is electrically coupled to the interlayer connector 115. The interlayer connector 115 electrically couples BL-complementary 114a on metal layer M1 to BL-complementary 114b on metal layer M0. The odd bitlines (e.g., BLₓ₊₁ 122b) remain on metal layer M0 in the twist region 130.

The twisting of BL-true and BL-complementary lines are preferably accomplished on metal layer M1. As illustrated in FIG. 5, the twist is accomplished by circumventing the interlayer connection of the other bitline. For example, the BL-complementary 114a loops around the interlayer connector 113a to the interlayer connector 115, which transfers BL-complementary from metal layer M1 to metal layer M0. Similarly, the BL-true 112b loops around the interlayer connector 115 to the interlayer connector 113a, which transfers BL-true from metal layer M1 to metal layer M0.

As one skilled in the art will appreciate, a memory utilizing an embodiment of the present invention may be fabricated wherein the bitlines may be positioned closer together because not every bitline contains a twist. Further, greater efficiencies are obtained by locating the twist on a metal layer wherein the adjacent bitline does not contain a bitline on the metal layer containing the twist. In this manner, the bitline architecture utilizes only two metal layers and, for example, usable for 2.83F and smaller bitline pitch designs.

Although particular embodiments of the invention have been described in detail, it is understood that the invention is not limited correspondingly in scope, but includes all changes, modifications, and equivalents coming within the spirit and terms of the claims appended hereto. For example, the locations of the sense amplifiers may be modified, the orientation of the bitlines on the metal layers may be changed, the locations of the interlayer connectors may be changed, the shape, configuration, and location of the switch region may be changed, different configurations other than alternating bitlines may be used, and the like. Accordingly, it is understood that this invention may be extended to other structures and materials, and thus, the specification and figures are to be regarded in an illustrative rather than a restrictive sense.

1. A signal pair comprising:
a first signal line on a first metal layer; and
a second signal line extending on a second metal layer to an interlayer connector and continuing on the first metal layer from the interlayer connector;
wherein the second signal line located on the second metal layer is substantially parallel to the first signal line, and the first signal line ends prior to the interlayer connector.

2. The signal pair of claim 1 wherein the signal pair forms a bitline-true and a bitline-complementary pair of a memory array.

3. The signal pair of claim 2 wherein the interlayer connector is located approximately half-way across the memory array.

4. The signal pair of claim 1 wherein the interlayer connector is positioned such that approximately one-half of the second signal is on the first metal layer and approximately one-half of the second signal is on the second metal layer.

5. Signal lines comprising:
a first signal pair having:
first signal line extending on a first metal layer to a first location; and
a second signal line extending on a second metal layer to a first interlayer connector and continuing from the first interlayer connector on the first metal layer; and
a second signal pair having
a third signal line extending on the first metal layer to a twist area, which moves the third signal line from the first metal layer to the second metal layer, the third signal line extending on the second metal layer from the twist area to a second interlayer connector and extending on the first metal layer from the second interlayer to an end location; and
a fourth signal line extending on the second metal layer to the twist area, which moves the fourth signal line from the second metal layer to the first metal layer, the fourth signal line extending from the twist area to an area approximately adjacent to the second interlayer connector.

6. The signal lines of claim 5 wherein the first signal pair comprises a first bitline pair, and the second signal pair comprises a second bitline pair.

7. The signal lines of claim 6 wherein the first bitline pair and the second bitline pair are arranged in an alternating manner.

8. The signal lines of claim 5 wherein portions of the first signal line and the second signal line located on the first metal layer are parallel to portions of the first signal line and the second signal line located on the second metal layer.

9. The signal lines of claim 5 wherein the twist area comprises a third interlayer connector electrically coupled to the third signal line and a fourth interlayer connector electrically coupled to the fourth signal line.

10. The signal lines of claim 9 wherein the third signal line circumvents the fourth interlayer connector and the fourth signal line circumvents the third interlayer connector.

11. A bitline archicture of a memory, the apparatus comprising:
a first bitline pair having a first bitline and a second bitline, the first bitline having a first portion, a second portion, and a third portion, the first portion and the third portion of the first bitline being on a first metal layer, the second portion of the first bitline being on a second metal layer, and the second bitline having a first portion and a second portion, the first portion of the second bitline being on the second metal layer and the second portion of the second bitline being on the first metal layer;
a second bitline pair having a third bitline and a fourth bitline, the third bitline being on the first metal layer, and the fourth bitline having a first portion and a second portion, the first portion of the fourth bitline being on the second metal layer and the second portion of the fourth bitline being on the first metal layer;
wherein the first bitline is substantially parallel to the second bitline and the third bitline is substantially parallel to the fourth bitline.

12. The bitline architecture of claim 11 wherein the first bitline pair is electrically coupled to a first sense amplifier and the second bitline pair is electrically coupled to a second amplifier.

13. The bitline architecture of claim 12 wherein the first sense amplifier and the second amplifier are located at opposing sides of a memory array.

14. The bitline architecture of claim 11 wherein the first bitline is a bitline-true line and the second bitline is a bitline-complementary line.

15. The bitline architecture of claim 11 wherein the third bitline is a bitline-true line and the fourth bitline is a bitline-complementary line.

16. The bitline architecture of claim 11 wherein bitlines corresponding to the first bitline pair and the second bitline pair are repeated in an alternating manner.

17. The bitline architecture of claim 11 wherein the first bitline and the second bitline switch metal layers in a twist area located on the second metal layer.

18. The bitline architecture of claim 17 wherein the twist area comprises a first interlayer connector electrically coupling the first portion of the first bitline on the first metal layer to the second portion of the first bitline on the second metal layer.

19. The bitline architecture of claim 17 wherein the twist area comprises a second interlayer connector electrically coupling the first portion of the second bitline on the second metal layer to the second portion of the second bitline on the first metal layer.
